(19) United States
(12) Patent Application Publication
(10) Pub. No.: US 2024/0178019 A1
(43) Pub. Date: May 30, 2024

(54) EQUIPMENT FRONT-END MODULES FOR SEMICONDUCTOR PROCESSING SYSTEMS AND METHODS OF MAKING SEMICONDUCTOR PROCESSING SYSTEMS

(71) Applicant: ASM IP Holding B.V., Almere (NL)

(72) Inventors: Mandar Deshpande, Phoenix, AZ (US); Gurupkar Singh Nerwal, Tempe, AZ (US); Joseph Kraus, Brandon, FL (US); Kyle Barrette, Gilbert, AZ (US)

(21) Appl. No.: 18/522,132

(22) Filed: Nov. 28, 2023

Related U.S. Application Data
(60) Provisional application No. 63/385,512, filed on Nov. 30, 2022.

(51) Int. Cl. H01L 21/67; C23C 16/44; H01J 37/32

(52) U.S. Cl. CPC H01L 21/67196; C23C 16/4409; H01J 37/32743; H01L 21/67167; H01L 21/67201; H01J 2237/184; H01J 2237/332

(57) ABSTRACT

An equipment front-end module (EFEM) includes a with a load port seat and a transfer robot seat. A fan filter unit is supported by the frame assembly and a controls box encloses the fan filter unit and is supported by the fan filter unit. The rear panel has a tunnel seat, is fixed to the frame assembly, and is separated from the load port seat by the transfer robot seat. One of (a) a plate body with an inboard passthrough and (b) a tunnel body with an outboard passthrough fixed at the tunnel seat and coupled to the frame assembly by the rear panel to space a process chamber with a quad chamber arrangement from the frame assembly differently along a transfer extending through the tunnel seat than a process module having a single or a dual chamber arrangement using a singular EFEM arrangement. Semiconductor processing systems and methods of making semiconductor processing systems are also described.

### CROSS-REFERENCE TO RELATED APPLICATION(S)

This application claims the benefit of U.S. Provisional Application 63/385,512 filed on Nov. 30, 2022, the entire contents of which are incorporated herein by reference.

### FIELD OF INVENTION

The present disclosure generally relates to fabricating semiconductor devices, and more particularly, to equipment front-end modules for semiconductor processing systems employed to fabricate semiconductor devices.

### BACKGROUND OF THE DISCLOSURE

Semiconductor processing systems commonly employ process modules to perform various processes during the fabrication of semiconductor devices including patterning, etching, material layer deposition, polishing or planarization, and metrology. Processing generally entails loading a substrate into the process module, performing a desired processing operation on the substrate, and thereafter transferring the substrate to another process module to perform another operation on the substrate. Loading the substrate into the process module typically entails positioning a pod carrying the substrate on a load port coupled to the process, removing the substrate from the pod, and transferring the substrate into the process module for processing. Once processing is complete the substrate is typically unloaded from the process module, returned to transfer pod, and carried within the pod to other semiconductor processing systems for further processing using, as appropriate according for the semiconductor device being fabricated.

In some semiconductor processing systems an equipment front-end module (EFEM) is employed to transfer substrates between the process module and the pod. The EFEM generally and interfaces pods carrying substrates with one or more process modules coupled to the EFEM using a substrate transfer robot housed within the EFEM, which transfers substrates between the pod carrying the substrates and the process module employed to process the substrates. The EFEM is typically spaced apart from the process module employed to process the substrates such that suitable service space is provided about the process module while limiting the floor space (e.g., footprint) occupied by the semiconductor processing system. The provision of service space about the process module allows maintainers to access the process module when servicing is required, such as to replace consumables and/or replace components in the unlikely event that a component fails. Limiting the floor space occupied by the semiconductor processing system generally limits cost of ownership of the semiconductor processing system, for example, by limiting cleanroom space required by the semiconductor processing system.

One challenge to providing service space about process modules while limiting floor space occupied by a semiconductor processing systems is that different process modules require different EFEM-process module spacing to ensure sufficient process space exists about the process module. For example, process modules that process singular substrates generally have smaller footprints than process modules employed to process two or more substrates at time. As a consequence, EFEMs are typically customized according to the footprint of the process module coupled to the EFEM to ensure that sufficient service space exists about the process module while limiting total floor space occupied by the semiconductor processing system. While customization is generally satisfactory insofar as ensuring access space exists and limiting total floor space occupied by the semiconductor processing system, customization can increase cost of EFEM manufacture and support of the EFEM once commissioned for service by the EFEM owner.

Such systems and methods have generally been satisfactory for their intended purposes. However, there remains a need for improved EFEM, semiconductor processing systems, and methods of making semiconductor processing systems. The present disclosure provides a solution to this need.

### SUMMARY OF THE DISCLOSURE

An equipment front-end module (EFEM) includes a with a load port seat and a transfer robot seat. A fan filter unit is supported by the frame assembly and a controls box encloses the fan filter unit and is supported by the fan filter unit. The rear panel has a tunnel seat, is fixed to the frame assembly, and is separated from the load port seat by the transfer robot seat. One of (a) a plate body with an inboard passthrough and (b) a tunnel body with an outboard passthrough fixed at the tunnel seat and coupled to the frame assembly by the rear panel to space a process chamber with a quad chamber arrangement from the frame assembly differently along a transfer extending through the tunnel seat than a process module having a single or a dual chamber arrangement using a singular EFEM arrangement.

In addition to one or more of the features described above, or as an alternative, further examples of the EFEM may include an inboard floor joist arranged along the transfer axis and an outboard floor joist axially spaced apart from the inboard floor joist along the transfer axis. The inboard floor joist and the outboard floor joist may define the transfer robot seat and a front-end substrate transfer robot fixed to the transfer robot seat.

In addition to one or more of the features described above, or as an alternative, further examples of the EFEM may include a first inboard post laterally offset from the transfer axis and a second inboard post separated from the first inboard post by the transfer axis. The first inboard post and the second inboard post may define the load port seat a load port may be fixed to the load port seat.

In addition to one or more of the features described above, or as an alternative, further examples of the EFEM may include that the frame assembly comprises includes a first outboard post laterally offset from the transfer axis and a second outboard post separated from the first outboard post by the transfer axis. The first outboard post and the second outboard post may support the rear panel.

In addition to one or more of the features described above, or as an alternative, further examples of the EFEM may include that the plate body is fixed at the tunnel seat and coupled to the frame assembly by the rear panel. The transfer axis may extend through the inboard passthrough defined by the plate body.

In addition to one or more of the features described above, or as an alternative, further examples of the EFEM may include a load lock module with a first front-end gate valve and a second front-end gate valve arranged along the transfer axis and abutting the plate body. The first front-end gate valve and the second front-end gate valve may be registered to the inboard passthrough.

In addition to one or more of the features described above, or as an alternative, further examples of the EFEM may include that the tunnel body is fixed at the tunnel seat and coupled to the frame assembly by the rear panel. The transfer axis may extend through the outboard passthrough defined by the tunnel body.

In addition to one or more of the features described above, or as an alternative, further examples of the EFEM may include a load lock module with a first front-end gate valve and a second front-end gate valve arranged along the transfer axis and abutting the plate body. The first front-end gate valve and the second front-end gate valve may be registered to the outboard passthrough defined by the tunnel body.

In addition to one or more of the features described above, or as an alternative, further examples of the EFEM may include that the plate body includes a plate body fastener pattern extending about the inboard passthrough, a plate body flange portion orthogonal relative to the plate body and a first plate body registration tab laterally offset from the transfer axis and between the plate body flange portion and the plate body fastener pattern. A second plate body registration tab may be separated from the first plate body registration tab by the transfer axis, the second plate body registration tab between the plate body flange portion and the plate body fastener pattern.

In addition to one or more of the features described above, or as an alternative, further examples of the EFEM may include that the tunnel body has a flange portion axially offset from a facia portion defining the outboard passthrough, a ceiling portion extending axially along the transfer axis and coupling the flange portion to the facia portion of the tunnel body, and a floor portion extending axially along the transfer axis and coupling the flange portion to the facia portion. The floor portion of the tunnel body may be separated from the ceiling portion of the tunnel body by the transfer axis.

In addition to one or more of the features described above, or as an alternative, further examples of the EFEM may include that the ceiling portion of the tunnel body is oblique relative to the transfer axis, that the floor portion is oblique relative to the transfer axis, and that the floor portion of the tunnel body slopes toward the flange portion at a greater angle than the ceiling portion of the tunnel body.

In addition to one or more of the features described above, or as an alternative, further examples of the EFEM may include that the flange portion incudes comprises an upper fastener plate parallel to the facia portion and extending upwards from the ceiling portion of the tunnel body, a lower fastener plate orthogonal to the upper fastener plate and extending axially from the floor portion of the tunnel body, a first tunnel body registration tab laterally offset from the transfer axis and separating the upper fastener plate from the lower fastener plate; and a second tunnel body registration tab separated from the first tunnel body registration tab by the transfer axis. The second tunnel body registration tab may separate the upper fastener plate from the lower fastener plate.

In addition to one or more of the features described above, or as an alternative, further examples of the EFEM may include that the floor portion of the tunnel body intersects the rear panel below a transfer space defined within the EFEM to return purge circulated through the tunnel body below substrates being transferred to and from the outboard passthrough defined by the tunnel body.

In addition to one or more of the features described above, or as an alternative, further examples of the EFEM may include a perforated plate supported within the EFEM between the fan filter unit and the transfer robot seat to distribute a purge fluid within a transfer space within the frame assembly.

In addition to one or more of the features described above, or as an alternative, further examples of the EFEM may include that the tunnel body has a perforated plate extension fixed within the tunnel body. The perforated plate extension may be parallel to the transfer axis. The perforated plate extension may abut the perforated plate supported in the EFEM.

In addition to one or more of the features described above, or as an alternative, further examples of the EFEM may include that the plate body abuts the perforated plate supported within the equipment front-end module in the tunnel seat.

In addition to one or more of the features described above, or as an alternative, further examples may include that the frame assembly of the EFEM has a symmetric arrangement.

In addition to one or more of the features described above, or as an alternative, further examples may include the frame assembly of the EFEM has an asymmetric arrangement.

In addition to one or more of the features described above, or as an alternative, further examples of the EFEM may include that the fan filter unit may have one and only one fan supported within a fan support body.

In addition to one or more of the features described above, or as an alternative, further examples of the EFEM may include four (4) fans distributed in two pairs on laterally opposite sides of the transfer axis.

A semiconductor processing system includes an EFEM as described above and further including a perforated plate supported within the EFEM between the fan filter unit and the transfer robot seat to distribute a purge fluid within the EFEM. A load lock module is axially spaced apart from the EFEM equipment front-end module along the transfer axis and one of (a) a process module having a dual chamber arrangement and (b) a process module having a quad chamber arrangement coupled the load lock and therethrough to the equipment front-end module.

In addition to one or more of the features described above, or as an alternative, further examples of the semiconductor processing system may include that the plate body is fixed at the tunnel seat and supported therethrough by the rear panel. The plate body may abut the perforated plate in the tunnel seat, and the process module may be coupled to the load lock module and therethrough to the EFEM.

In addition to one or more of the features described above, or as an alternative, further examples of the semiconductor processing system may include that the tunnel body is fixed at the tunnel seat and supported therethrough by the rear panel. The tunnel body may include a perforated plate extension fixed therein and abutting the perforated plate within the tunnel seat. The process module having the quad chamber arrangement may be coupled to the load lock module and therethrough to the EFEM.

A method of making a semiconductor processing system includes, at an EFEM as described above, removing a plate body with an inboard passthrough from the tunnel seat, fixing a tunnel body with an outboard passthrough at the tunnel seat and therethrough to the frame assembly by the rear panel, and coupling a load lock module to the outboard passthrough defined by the tunnel body. A substrate transfer module may be couple to the load lock module and a process module having a quad chamber arrangement coupled to the substrate transfer module and therethrough to the equipment front-end module through the load lock module. The process module with the quad chamber arrangement is spaced differently from the frame assembly along the transfer than a process module having a single or a dual chamber arrangement using a singular equipment front-end module arrangement.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the present disclosure are described below with reference to the drawings of certain examples, which are intended to illustrate and not to limit the present disclosure.

FIG. 1 is a schematic view of a semiconductor processing system in accordance with the present disclosure, showing an equipment front-end module (EFEM) connected to a process module with a single chamber through a load lock module and a transfer module;

FIG. 2 is perspective view of the EFEM of FIG. 1 according to an example of the present disclosure, showing a frame assembly having a load port seat and transfer robot seat located within an interior of the EFEM;

FIG. 3 is an exploded view of the EFEM of FIG. 1 according to an example of the present disclosure, showing a controls box and a fan filter unit supported above the frame assembly exploded away from the frame assembly;

FIG. 4 is a perspective view of the fan filter unit of the EFEM of FIG. 1, showing a fan fluidly coupling an intake and a chemical filter seated above the fan to a distribution plenum and a particulate filter seated below the fan;

FIG. 5 is an outboard perspective view of the EFEM of FIG. 1 according to an example of the present disclosure, showing a plate body with an inboard passthrough extending about a transfer axis fixed at a tunnel seat and supported by a rear panel of the EFEM to space process modules having single and dual chamber arrangements from the EFEM;

FIG. 6 is an inboard perspective view of the plate body of FIG. 5 according to an example of the present disclosure, showing a fastener pattern and plate body registration tabs extending about the inboard passthrough to position and fix the plate body at the tunnel seat;

FIG. 7 is an outboard perspective view of the EFEM of FIG. 1 according to another example of the present disclosure, showing a tunnel body with an outboard passthrough fixed at the tunnel seat and supported by the rear panel of the EFEM to space to space process modules having quad chamber arrangements from the EFEM;

FIG. 8 is an inboard perspective view of the tunnel body of FIG. 7 according to an example of the present disclosure, showing a fastener pattern and tunnel body registration tabs axially offset from the outboard passthrough along the transfer axis;

FIGS. 9 and 10 are plan views of the EFEM of FIG. 1 according to an example, showing frame assemblies having an asymmetric arrangement and a symmetric arrangement;

FIG. 11 is a plan view of a semiconductor processing system including the EFEM of FIG. 1 according to another example of the present disclosure, showing the plate body fixed at the tunnel seat and spacing a process module having a dual chamber arrangement from the EFEM by a first distance along the transfer axis;

FIG. 12 is a plan view of a semiconductor processing system including the EFEM of FIG. 1 according to a further example of the present disclosure, showing the tunnel body fixed at the tunnel seat and spacing a process module having a quad chamber arrangement from the EFEM by a second distance along the transfer axis; and

FIG. 13 is a block diagram of a method of making a semiconductor processing system, showing operations of the method according to an illustrative and non-limiting example.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

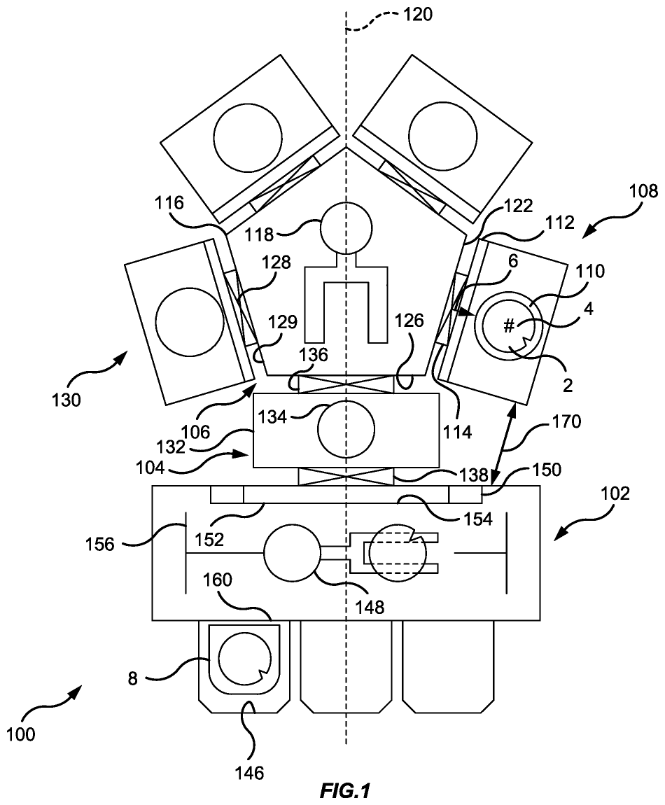

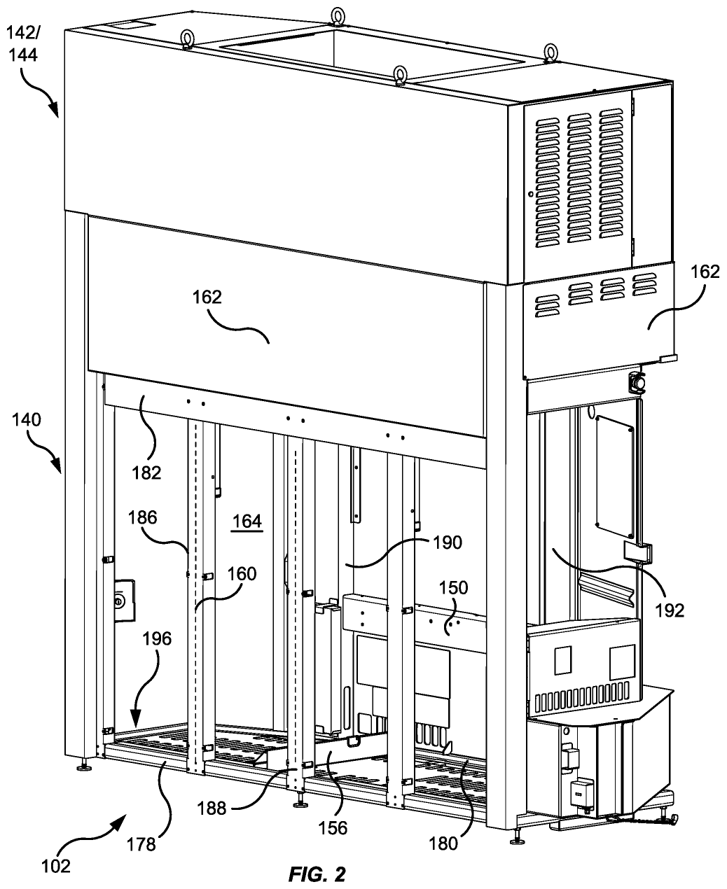

Reference will now be made to the drawings wherein like reference numerals identify similar structural features or aspects of the subject disclosure. For purposes of explanation and illustration, and not limitation, a partial view of an example of a semiconductor processing system with an equipment front-end module (EFEM) in accordance with the present disclosure is shown in FIG. 1 and is designated generally by reference character 100. Other examples of semiconductor processing systems, EFEMs, and methods of making semiconductor processing systems in accordance with the present disclosure, or aspects thereof, are provided in FIGS. 2-13, as will be described. The systems and methods of the present disclosure may be used to interface semiconductor processing systems having process modules with different numbers of process chambers to material handling systems using an singular (e.g., common) EFEM architecture, such as in semiconductor processing systems having cluster-type platforms with process chambers employed to deposit material layers onto substrates, though the present disclosure is not limited to cluster-type platforms or to semiconductor processing systems employed for material layer deposition in general.

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes, such as 200-millimeter or 300-millimeter silicon wafers. Substrates may be made from semiconductor materials, including, for example, silicon, silicon germanium, silicon oxide, gallium arsenide, gallium nitride and silicon carbide.

Referring to FIG. 1, the semiconductor processing system 100 is shown. The semiconductor processing system 100 generally includes an EFEM 102, a load lock module 104, a back-end transfer module 106, and a process module 108. In the illustrated example the process module 108 is one of four (4) process modules each having a singular (i.e., one and only one) process chamber 110, a material layer precursor source 112, and process module gate valve 114. The process chamber 110 is configured to support a substrate 2 during deposition of a material layer 4 onto the substrate using a material layer precursor 6 provided by the material layer precursor source 112. The material layer precursor source 112 is connected to the process chamber 110 and is configured to provide the material layer precursor 6 to the process chamber 110. The process module gate valve 114 couples the process module 108 to the back-end transfer module 106 and is configured to provide selective communication between process module 108 and the back-end transfer module 106. Examples of suitable gate valves include 04.2 HV transfer valves, available from VAT Group AG of Haag, Switzerland. In certain examples the material layer precursor 6 may include a material layer precursor suitable for use in a chemical vapor deposition (CVD) material layer deposition process, such as an epitaxial deposition process. In accordance with certain examples, the material layer precursor may include a material layer precursor suitable for use in an atomic layer deposition (ALD) material layer deposition process. It is also contemplated that that material layer precursor 6 may include a material layer precursor suitable for use in a plasma-enhanced material layer deposition process, such as in a plasma-enhanced CVD or a plasma-enhanced ALD material layer deposition technique. Although shown and described herein as having a specific arrangement, e.g., a process module with a single process chamber, it is to be understood and appreciated semiconductor processing systems having process modules with more than one process chamber may also benefit from the present disclosure.

The back-end transfer module 106 includes a back-end transfer chamber 116 and a back-end substrate transfer robot 118. The back-end transfer chamber 116 is arranged along a transfer axis 120 and has a first process module facet 122, a second process module facet 124, and a load lock facet 126. The first process module facet 122 is angled (e.g., oblique) relative to the transfer axis 120 and is connected to the process module gate valve 114. The second process module facet 124 is also angled (e.g., oblique) relative the transfer axis 120, may further be angled (or oblique) relative to the first process module facet 122, and is configured to seat thereon a second gate valve 128 to couple a second process module 130 to the back-end transfer module 106. The load lock facet 126 is substantially orthogonal relative to the transfer axis 120, couples the first process module facet 122 to the second process module facet 124, and is coupled to the load lock module 104 for transfer of the substrate between the back-end transfer module 106 and the load lock module 104. In certain examples the back-end transfer chamber 116 may have pentagonal shape, such a regular or an irregular pentagonal shape. It is also contemplated that the back-end transfer chamber 116 may have a different number of facts than shown in the illustrated example, for example have fewer than five (5) facets or more than five (5) facets, and remain within the scope of the present disclosure. It is contemplated that the back-end substrate transfer robot 118 be supported within the back-end transfer chamber 116 for movement relative to the back-end transfer chamber 116 to transfer the substrate 2 between the load lock module 104 and the process module 108. In the illustrated example the back-end substrate transfer robot 118 has a single end effector configured to carry a single substrate between the load lock module 104 and the process module 108. As will be appreciated by those of skill in the art in view of the present disclosure, the back-end substrate transfer robot 118 may have more than one end effector and remain within the scope of the present disclosure.

The load lock module 104 includes a load lock chamber 132, a transfer stage 134, a back-end gate valve 136, and a front-end gate valve 138. The transfer stage 134 is arranged within the load lock chamber 132 and is configured to support the substrate 2 during transfer between the back-end transfer module 106 and the EFEM 102. The back-end gate valve 136 couples the load lock chamber 132 to the back-end transfer chamber 116 and is configured to provide selective communication between the load lock module 104 and the back-end transfer module 106 for transfer of the substrate 2 between the load lock module 104 and the back-end transfer module 106. The front-end gate valve 138 couples the load lock chamber 132 to the EFEM 102 and is configured to provide selective communication between the load lock module 104 and the EFEM 102 for transfer of the substrate 2 between the load lock module 104 and the EFEM 102. In the illustrated example the load lock module 104 has a singular (i.e., one and only one) transfer stage. As will be appreciated by those of skill in the art in view of the present disclosure the load lock module 104 may have more than one transfer stage and remain within the scope of the present disclosure.

The EFEM 102 is connected to load lock module 104 and includes a frame assembly 140 (shown in FIG. 2), a fan filter unit 142 (shown in FIG. 2), a controls box 144 (shown in FIG. 2), a load port 146, and a front-end substrate transfer robot 148. The frame assembly 140 is coupled to the load lock module 104 by a rear panel 150. More specifically, the frame assembly 140 is coupled to front-end gate valve 138 by a plate body 152, which is fixed at a tunnel seat 154 defined by the rear panel 150, the rear panel 150 in turn fixed to the frame assembly 140. The front-end substrate transfer robot 148 is supported within the frame assembly 140 at a transfer robot seat 156, and is configured to transfer the substrate 2 between the load lock module 104 and the EFEM 102. The load port 146 is fixed to a load port seat 160 and is configured to seat thereon a pod 8, such as a front-opening unified pod carrying the substrate 2, for interfacing the semiconductor processing system 100 to a material handling system, such as an automated material handling system. Examples of suitable front-end robots include NTS series wafer handling robots, available from Kawasaki Heavy Industries Ltd. of Kobe, Japan. Examples of suitable load ports include TAS300 Type J1 load ports, available from the TDK Corporation of Tokyo, Japan. In the illustrated example the EFEM 102 has three load ports. As will be appreciated by those of skill in the art in view of the preset disclosure, the EFEM 102 may have fewer or additional load ports in other examples and remain within the scope of the present disclosure.

With reference to FIG. 2, a portion of the EFEM 102 is shown. The EFEM 102 generally includes the frame assembly 140, the fan filter unit 142, the controls box 144, and a panel arrangement 162 including the rear panel 150. The frame assembly 140 defines the load port seat 160 seating the load port 146 (shown in FIG. 1) and the transfer robot seat 156 seating the front-end substrate transfer robot 148 (shown in FIG. 1). The fan filter unit 142 is supported by the frame assembly 140 at a location above the transfer robot seat 156 and the front-end substrate transfer robot 148. The controls box 144 encloses the fan filter unit 142 and is supported at a location above the frame assembly 140 by the fan filter unit 142. The panel arrangement 162 is fixed to the frame assembly 140 and fluidly separates a substrate transfer volume 164 within the frame assembly 140 from the environment external to the EFEM 102

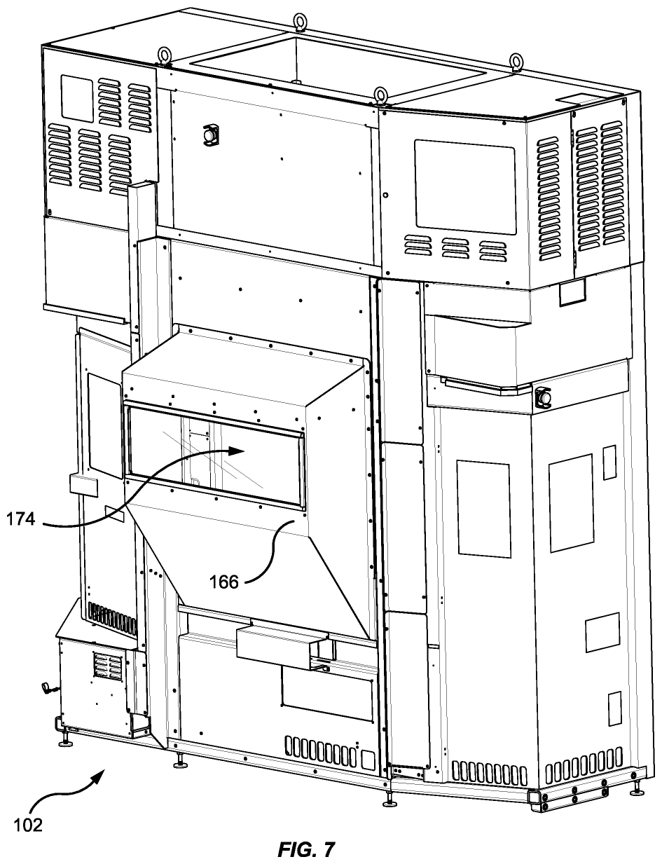

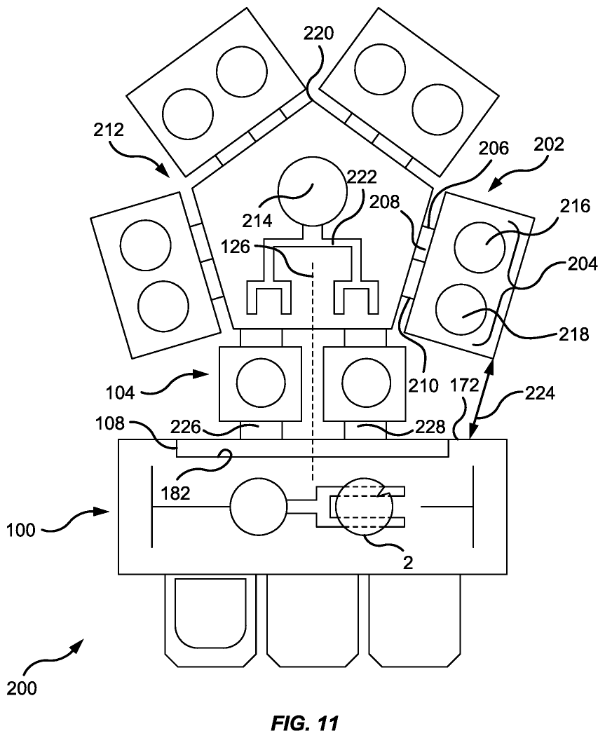

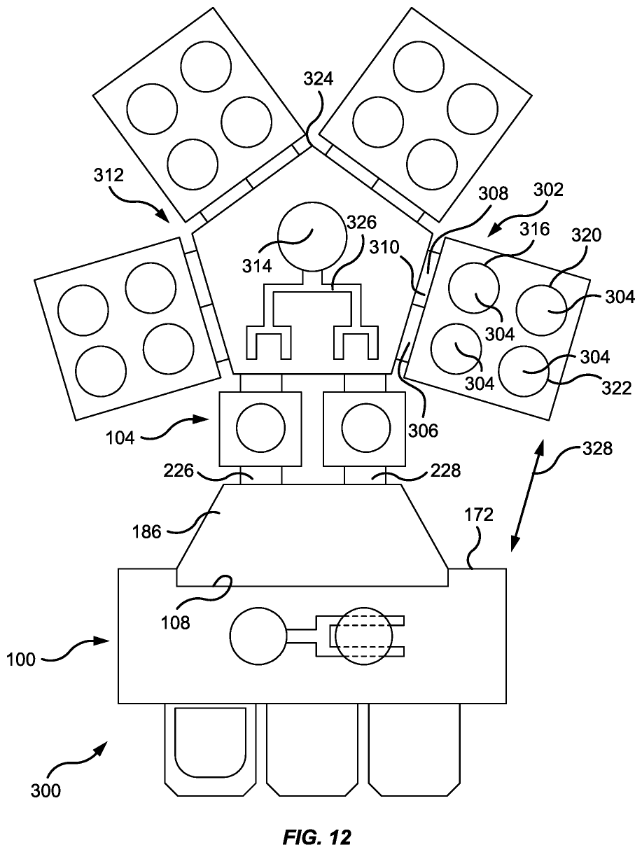

It is contemplated that the rear panel 150 be fixed to the frame assembly 140 along the transfer axis 120 at a location separated from the load port seat 160 by the transfer robot seat 156, that the rear panel 150 define the tunnel seat 154, and that one of (a) the plate body 152 (shown in FIG. 1) and a tunnel body 166 (shown in FIG. 7) be fixed at the tunnel seat 154 to space process modules having different numbers of process chambers by different spacing distances using a singular EFEM architecture. For example, in semiconductor processing systems having process modules with a single process chamber or a dual process chambers, the plate body 152 may define an inboard passthrough 168 (shown in FIG. 7) coplanar with the rear panel 150 to space the process modules by a first spacing distance 170 (shown in FIG. 1) or a second spacing distance 224 (shown in FIG. 11). In semiconductor processing systems having process modules with more than two process modules, e.g., process modules having four process modules, the tunnel body 166 define an outboard passthrough 174 axially offset from the rear panel 150 to space the process modules by a third spacing distance 328 (shown in FIG. 12). As will be appreciated by those of skill in the art in view of the present disclosure, configuring the EFEM 102 to support either the plate body 152 or the tunnel body 166 eliminates the need to customize the EFEM 102 according to the number of process chambers in the process modules couples to the EFEM 102, limiting cost and complexity otherwise associated with such customization.

The frame assembly 140 includes an inboard floor joist 178, an outboard floor joist 180, an inboard ceiling joist 182, and an outboard ceiling joist 184. The frame assembly 140 also includes a first inboard post 186, a second inboard post 188, a first outboard post 190, and a second outboard post 192. The inboard floor joist 178 and the outboard floor joist 180 are arranged along the transfer axis 120, laterally span the frame assembly 140, and define the transfer robot seat 156. The outboard floor joist 180 is axially spaced apart from the inboard floor joist 178 along the transfer axis 120, and the inboard floor joist 178 axially separates the load port seat 160 from the outboard floor joist 180. The inboard ceiling joist 182 and the outboard ceiling joist 184 are similar to the inboard floor joist 178 and the outboard floor joist 180, respectively, are additionally supported above the front-end substrate transfer robot 148 (shown in FIG. 1), and are further separated from the inboard floor joist 178 and the outboard floor joist 180 by the front-end substrate transfer robot 148 and substrate transfer volume 164.

The first inboard post 186 is laterally offset from transfer axis 120, extends upwards from the inboard floor joist 178, and couples the inboard ceiling joist 182 to the inboard floor joist 178. The second inboard post 188 is laterally offset from transfer axis 120, extends upwards from the inboard floor joist 178 to couple the inboard ceiling joist 182 of the inboard floor joist 178, and is additionally arranged on a side of the transfer axis 120 laterally opposite the first inboard post 186. It is contemplated that at least one of the first inboard post 186 and the second inboard post 188 define the load port seat 160, that the load port 146 be fixed at the load port seat 160 and therethrough to the first inboard post 186 and the second inboard post 188, and that the spacing between the first inboard post 186 and the second inboard post 188 enable the pod 8 (shown in FIG. 1) to communicate with the substrate transfer volume 164. It also contemplated that one or floor stringers and one or more ceiling stringers couple the inboard floor joist 178 to the outboard floor joist 180 and the inboard ceiling joist 182 to the outboard ceiling joist 184, respectively, and that a supply plenum 194 and a return plenum 196 be defined above and below the front-end substrate transfer robot 148, respectively, to communicate a purge fluid 10 within the frame assembly 140 via a perforated plate 198 supported above the substrate transfer volume 164.

The first outboard post 190 is similar to the first inboard post 186, is additionally axially offset from the first inboard post 186, and is laterally offset from the transfer axis 120. The first outboard post 190 is further separated from the first inboard post 186 by the front-end substrate transfer robot 148 and couples the outboard ceiling joist 184 to the outboard floor joist 180. The second outboard post 192 is similar to the second inboard post 188, is axially offset from the second inboard post 188 along the transfer axis 120 and is arranged on a side of the transfer axis 120 laterally offset from the first outboard post 190, and also couples the outboard ceiling joist 184 to the outboard floor joist 180. It is contemplated that the first outboard post 190 and the second outboard post 192 define a rear panel fastener pattern, and that the rear panel 150 be fixed at the rear panel fastener pattern such that the transfer axis 120 extends through the tunnel seat 154 (shown in FIG. 1) defined by the rear panel 150.

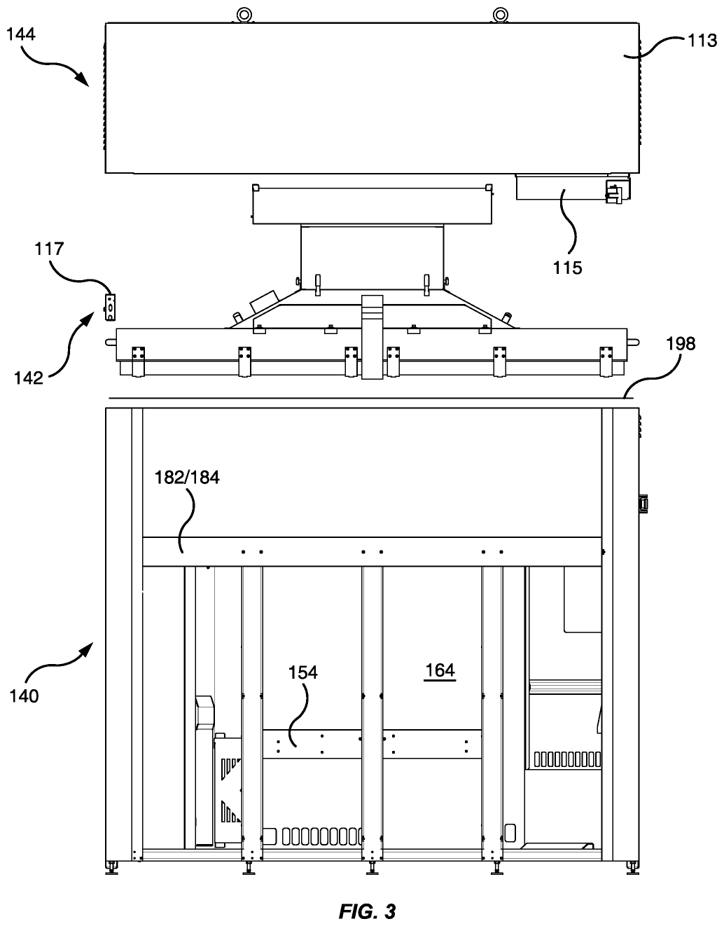

With reference to FIG. 3, the controls box 144 is supported by the fan filter unit 142 and includes a controls box enclosure 113. It is contemplated that the controls box enclosure 113 be supported above the frame assembly 140, enclose the fan filter unit 142, and house one or more computing device 115. In certain examples the one or more computing device 115 may be operably connected to the first process module 108 (shown in FIG. 1) and/or the second process module 130 (shown in FIG. 1). In accordance with certain examples, the one or more computing device 115 may be operably connected to the back-end substrate transfer robot 118 (shown in FIG. 1) and/or the front-end substrate transfer robot 148 (shown in FIG. 1). It is contemplated that the one or more computing device 115 may be operably connected to the fan 103 to control flow of the purge fluid 10 driven into the enclosure 158, the one or more computing device 115 cooperating with a sensor (e.g., a pressure sensor) in communication with the substrate transfer volume 164 to control pressure differential between the interior of the EFEM 102 and the ambient environment outside of the EFEM 102. It is also contemplated that, in accordance with certain examples, the one or more computing device 115 may control communication between processors associated with the two of the more of the modules of the semiconductor processing system 100 (shown in FIG. 1), such as in examples having networked computing devices and/or a distributed computing environment.

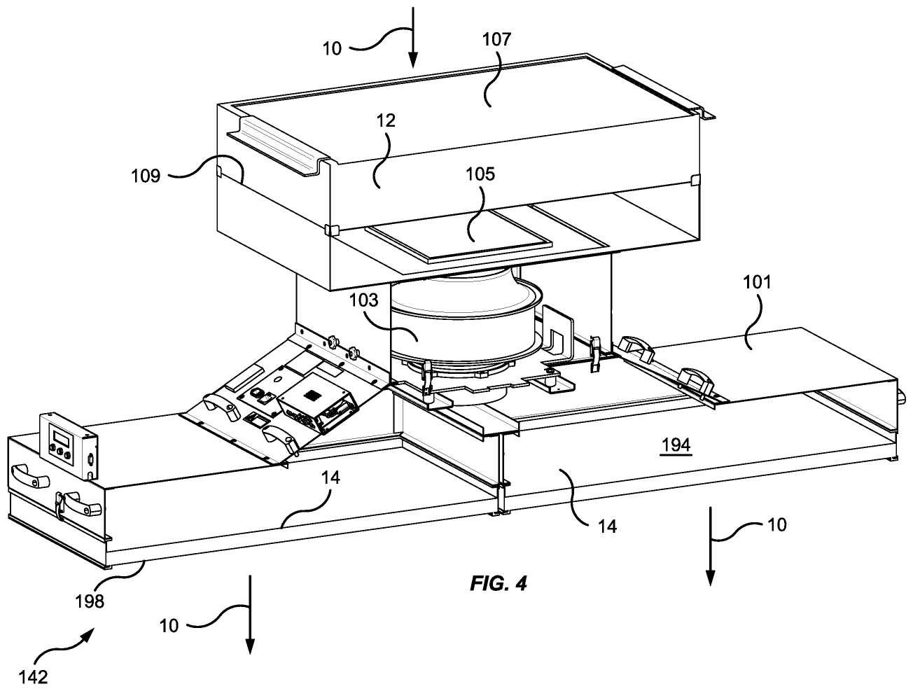

With reference to FIG. 4, the fan filter unit 142 includes a fan support body 101, a fan 103, and a mesh body 105. The fan support body 101 is supported by the inboard ceiling joist 182 (shown in FIG. 2) and the outboard ceiling joist 184 (shown in FIG. 3) of the frame assembly 140. The fan support body 101 further defines a purge fluid intake 107, a chemical filter seat 109, and a particulate filter seat 111. The purge fluid intake 107 is spaced apart from the fan 103 by the chemical filter seat 109 to communicate the purge fluid 10 ingested at the purge fluid intake 107 to the fan 103. In certain examples, the purge fluid intake 107 may be fluidly coupled to the ambient environment outside of the EFEM 102, for example, to a cleanroom atmosphere external to the semiconductor processing system 100 (shown in FIG. 1).

The chemical filter seat 109 is arranged between the purge fluid intake 107 and the mesh body 105 and is configured to seat a chemical filter 12. The mesh body 105 is supported within the fan support body 101 between the chemical filter seat 109 and the fan 103 and is configured to separate a user servicing (positioning and/or replacing) the chemical filter 12 seated on the chemical filter seat 109 from the fan 103, limiting (or eliminating) the need to cease operation of the fan 103 during service of the chemical filter 12 seated on the chemical filter seat 109. The fan 103 is in turn configured to draw the purge fluid 10 received at the purge fluid intake 107 through the chemical filter 12 supported at the chemical filter seat 109 and is this respect is supported for rotation within the fan support body 101 between the mesh body 105 and the particulate filter seat 111. In certain examples, the fan 103 may include a single fan, the single fan overlaying the transfer axis 120 in such examples and limiting cost of the EFEM 102 (shown in FIG. 1). In accordance with certain examples, the fan 103 may be one of a plurality of fans. For example, the fan filter unit 142 may include two pairs of fans supported about the front-end substrate transfer robot 148 on laterally opposite sides of the transfer axis 120 (shown in FIG. 1). As will be appreciated by those of skill in the art in view of the present disclosure, examples of having a plurality of fans provide operational flexibility, for example, by enabling compensation for flow environment changes within the substrate transfer volume 164 (shown in FIG. 1) due to movement of the front-end substrate transfer robot 148 (shown in FIG. 1) with fan speed change.

The particulate filter seat 111 is configured to seat a particulate filter 14 to remove particulate from the purge fluid 10 driven by the fan 103 prior to entry to the substrate transfer volume 164. In this respect the particulate filter seat 111 is arranged within the frame assembly 140 at a location between the fan 103 and the front-end substrate transfer robot 148. More specifically, the particulate filter seat 111 is arranged between the fan 103 and the perforated plate 198, is spaced apart from the perforated plate 198 by the supply plenum 194, and fluidly couples the fan 103 to the supply plenum 194 such that the perforated plate 198 may uniformly provide the purge fluid 10 laterally and axially to the substrate transfer volume 164 defined within the frame assembly 140. It is contemplated that the particulate filter seat 111 be configured to seat thereon one or more particulate filters, e.g., one or more ultra-low penetration air (ULPA) particulate filter, to impound particulate entrained within the purge fluid 10 driven by the fan 103, such as one or more ULPA filters having a standard (i.e., not customized) size. It is also contemplated that the perforated plate 198 may have a uniform distribution of perforations to provide the purge fluid 10 to the substrate transfer volume 164 in a generally laminar flow pattern.

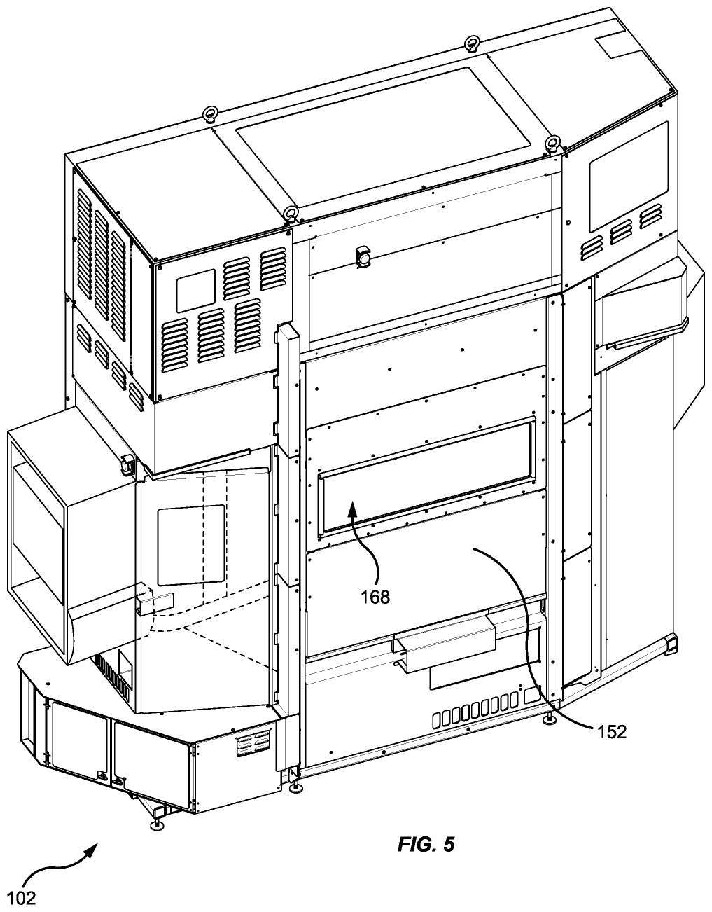

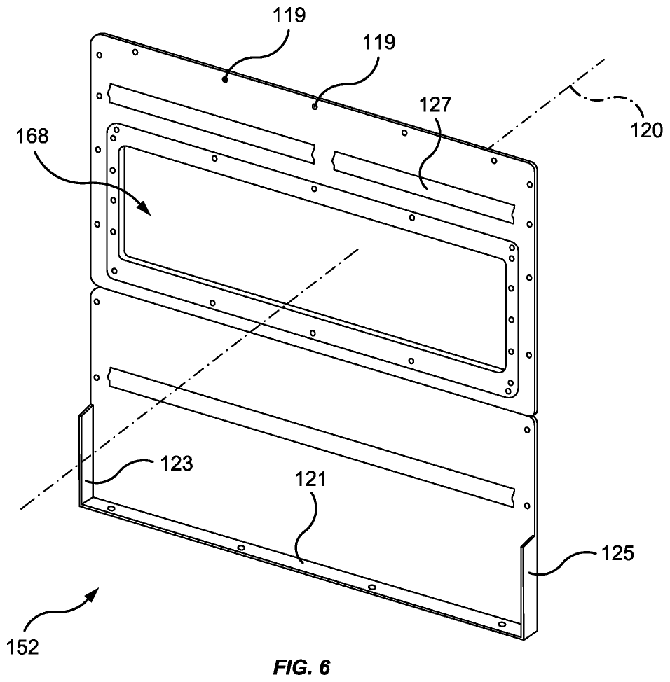

Referring now to FIGS. 5 and 6, the plate body 152 is shown. The plate body 152 defines the inboard passthrough 168 and extends about the inboard passthrough 168. The plate body 152 further defines a plate body fastener pattern 119 and has a plate body flange portion 121, a first plate body registration tab 123, and a second plate body registration tab 125. The plate body fastener pattern 119 extends about the inboard passthrough 168 and corresponds to the tunnel seat 154 (shown in FIG. 3). The plate body flange portion 121 is orthogonal relative to the plate body 152 and is substantially parallel to the transfer axis 120. The first plate body registration tab 123 is laterally offset from the plate body flange portion 121 and the transfer axis 120. The first plate body registration tab 123 is further located between the plate body flange portion 121 and inboard passthrough 168. The second plate body registration tab 125 is similar to the first plate body registration tab 123, additionally extends in parallel with the first plate body registration tab 123 on a side of the transfer axis 120 opposite the first plate body registration tab 123, and is further spaced apart from the first plate body registration tab 123 by the plate body flange portion 121.

In certain examples, the plate body flange portion 121, the first plate body registration tab 123, and the second plate body registration tab 125 may cooperate to enable installation of the plate body 152 with a single installer using a place and pivot technique. For example, the orthogonal orientation of the plate body flange portion 121 allows installer seat the plate body 152 in the tunnel seat 154 (shown in FIG. 3) at an angle relative to the transfer axis 120 such that weight of the plate body 152 is initially supported by the tunnel seat 154 through the plate body flange portion 121. The single installer may then pivot the plate body 152 about the plate body flange portion 121 toward the rear panel 150 until apertures of the plate body fastener pattern 119 align to corresponding fastener aperture defined in the rear panel 150 about the tunnel seat 154. Alignment may be facilitated by the first plate body registration tab 123 and the second plate body registration tab 125, which may guide seating of the plate body 152 during the pivoting motion, and which may self-center the plate body 152 within the tunnel seat 154 according to play each tab. In this respect the first plate body registration tab 123 and the second plate body registration tab 125 may provide incrementally increasing lateral centering force during pivoting according to increasing tab contact with the tunnel seat 154. The first plate body registration tab 123 and the second plate body registration tab 125 further provide an interference fit within the tunnel seat 154 at conclusion of pivoting movement, freeing the installer's hands and enabling the installer to fasten the plate body 152 to the rear panel 150 without having manually retain the plate body 152 in the tunnel seat 154.

In certain examples, a portion of an outboard edge of the perforated plate 198 may abut the plate body 152 within the tunnel seat 154 once the plate body 152 is seated in the tunnel seat 154. The perforated plate 198 edge may abut the plate body 152 at a location above the inboard passthrough 168, the perforated plate 198 providing a laminar flow of the purge fluid 10 (shown in FIG. 4) to substrates during staging at and/or transfer through the inboard passthrough 168. In accordance with certain examples, a perforated plate seat 127 may be affixed to an interior face of the plate body 152, the perforated plate seat 127 both supporting the perforated plate 198 within the tunnel seat 154 once installed and providing rigidity to the plate body 152 during installation to facilitate registration of the plate body fastener pattern 119 with the corresponding fastener pattern on the rear panel 150. An intermediate lateral stiffener may also be connected to the plate body at a location between the inboard passthrough 168 and the first plate body registration tab 123 and the second plate body registration tab 125 to facilitate the aforementioned place and pivot single installer technique.

It is contemplated that, when the plate body 152 is fixed to the tunnel seat 154 (shown in FIG. 3), the transfer axis 120 extend through the inboard passthrough 168. It is further contemplated that the front-end gate valve 138 (shown in FIG. 1) be registered to inboard passthrough 168 in examples where the EFEM 102 is coupled to a single chamber or dual chamber process modules, an axial thickness of plate body 152 thereby defining the first spacing distance 170 (shown in FIG. 1) or the second spacing distance 172 (shown in FIG. 11). As will be appreciated by those of skill in the art in view of the present disclosure, registering the front-end gate valve 138 allows the front-end substrate transfer robot 148 to transfer substrates, e.g. the substrate 2, between the transfer stage 134 and the load port 146. As will also be appreciated by those of skill in the art in view of the present disclosure, the axial thickness of the plate body 152 defines spacing between the EFEM 102 and the process module coupled to the EFEM 102, enabling the spacing distance to comply with service space size requirements of the process module coupled to the EFEM 102.

With continuing reference to FIG. 3, the perforated plate 198 (shown in FIG. 3) is configured to distribute purge driven by the fan 103 within the enclosure 158 and in this respect fluidly couples a supply plenum 194 defined between the fan 103 and the front-end substrate transfer robot 148. It is contemplated that the perforated plate 198 abut the plate body 152 at a location above the inboard passthrough 168, the perforated plate 198 thereby distributing a portion of the purge fluid 10 traversing the perforated plate 198 across substrates (e.g., the substrate 2) during transfer between the load port 146 and the load lock module 104 as a laminar flow. In certain examples the perforations defined by the perforated plate 198 may be symmetrically distributed relative to the transfer axis 120, such as in examples where the EFEM 102 has a symmetric footprint 165 (shown in FIG. 5). In this respect a first lateral side of the EFEM 102 may mirror a second lateral side of the EFEM 102 about the transfer axis 120. In accordance with certain examples, the perforations defined by the perforated plate 198 may be asymmetrically distributed relative to the transfer axis 120, such as in examples where the EFEM 102 has an asymmetric footprint, such as accommodate accessories arranged within the EFEM 102. As will be appreciated by those of skill in the art in view of the present disclosure, examples of the EFEM 102 provide purge fluid flow conditions between the load port 146 and the front-end gate valve 138 more similar to flow conditions between the load port 146 and the front-end gate valve 138 than possible EFEMs having asymmetric footprints, potentially limiting variation among substrates processed by the semiconductor processing system 100.

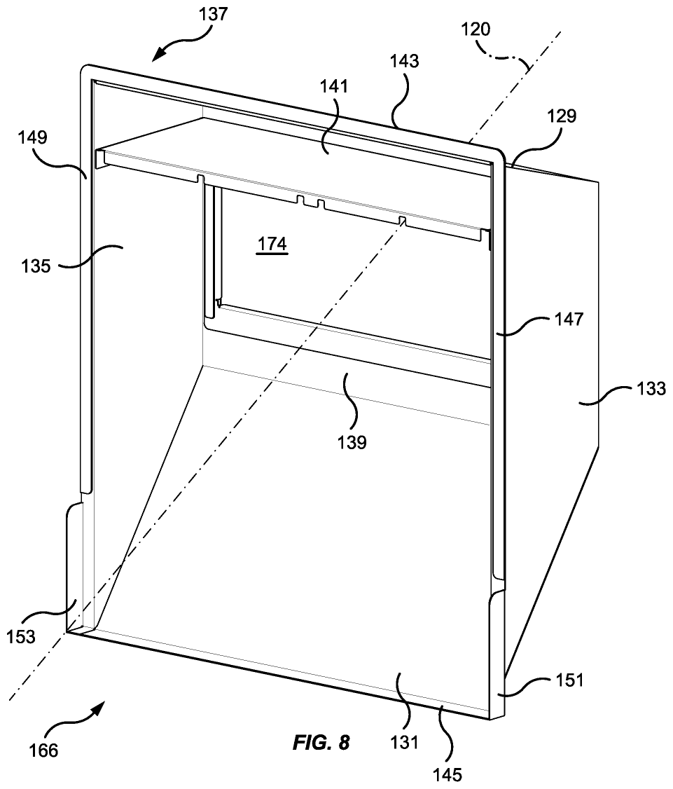

With reference to FIGS. 7 and 8, the tunnel body 166 is shown. The tunnel body 166 includes a ceiling portion 129, a floor portion 131, a first sidewall portion 133, and a second sidewall portion 135. The tunnel body 166 also includes a flange portion 137, a facia portion 139, and perforated plate extension 141. The ceiling portion 129 of the tunnel body 166 is oblique relative to the flange portion 137 of the tunnel body 166. The ceiling portion 129 may also be oblique relative to the transfer axis 120 when the tunnel body 166 is fixed to the tunnel seat 154 (shown in FIG. 1) of the rear panel 150 (shown in FIG. 1). The floor portion 131 of the tunnel body 166 is oblique relative to the flange portion 137 and slopes toward the ceiling portion 129 of the tunnel body 166. The floor portion 131 may also be oblique relative to the transfer axis 120 when the tunnel body 166 is fixed to the tunnel seat 154 of the rear panel 150.

The perforated plate extension 141 is fixed within the tunnel body 166 between the ceiling portion 129 and the floor portion 131 of the tunnel body 166. The perforated plate extension 141 further couples the first sidewall portion 133 of the tunnel body 166 to the second sidewall portion 135 of the tunnel body 166, and extends axially between the facia portion 139 and the flange portion 137 of the tunnel body 166. The perforated plate extension 141 may also be parallel to the transfer axis 20 when the tunnel body 166 is fixed to the tunnel seat 154 (shown in FIG. 1) of the rear panel 150 (shown in FIG. 1). In certain examples, the oblique angle of the ceiling portion 129 may cooperate with perforations defined within the perforated plate extension 141 to provide a portion of the purge fluid 10 (shown in FIG. 4) as a laminar flow to substrates staged or being transferred through the tunnel body 166. In accordance with certain examples, the oblique angle of the floor portion 131 may cooperate with perforations defined within the perforated plate extension 141 to return the portion of the purge fluid 10 to the frame assembly 140 (shown in FIG. 2) at a location below the substrate transfer volume 164 (shown in FIG. 2) for recirculation through the return plenum 196. In this respect the oblique angle defined by the floor portion 131 of the tunnel body 166 may be anti-supplement (i.e., not summing to 180-degrees) to the oblique angle defined by ceiling portion 129 of the tunnel body 166.

The first sidewall portion 133 of the tunnel body 166 extends between the ceiling portion 129 and the floor portion 131 of the tunnel body 166. The first sidewall portion 133 further extends between the flange portion 137 of the tunnel body 166 and the facia portion 139 of the tunnel body 166. In certain examples the first sidewall portion 133 may be substantially parallel to the transfer axis 120. In accordance with certain examples, the first sidewall portion 133 may be angled (e.g., oblique) relative the transfer axis 120. The second sidewall portion 135 of the tunnel body 166 is similar to the first sidewall portion 133 of the tunnel body 166 and is additionally separated from the first sidewall portion 133 by the transfer axis 120. It is contemplated that the second sidewall portion 135 be spaced apart from the first sidewall portion 133 by the facia portion 139 of the tunnel body 166. In this respect it is contemplated that the outboard passthrough 174 be defined by the facia portion 139 of the tunnel body 166, the facia portion 139 extending about the outboard passthrough 174. In further respect, the facia portion 139 of the tunnel body 166 (and thereby the outboard passthrough 174) may be axially spaced from the flange portion 137 by the first sidewall portion 133 and the second sidewall portion 135 of the tunnel body 166 such that the outboard passthrough 174 is axially offset (and thereby outboard) of the rear panel 150.

The flange portion 137 of the tunnel body 166 is configured to fix the tunnel body 166 to the tunnel seat 154 and in this respect includes an upper fastener plate 143, a lower fastener plate 145, a first sidewall fastener plate 147, and a second sidewall fastener plate 149. The flange portion 137 also includes a first tunnel body registration tab 151 and a second tunnel body registration tab 153. The upper fastener plate 143 extends from the ceiling portion 129 in a direction opposite the floor portion 131 of the tunnel body 166, laterally spans the ceiling portion 129 of the tunnel body 166, and defines an upper fastener pattern conforming (in part) to the fastener pattern defined by the tunnel seat 154. The lower fastener plate 145 extends from the floor portion 131 of the tunnel body 166 in a direction opposite the facia portion 139, laterally spans the floor portion 131 of the tunnel body 166, and defines a lower fastener pattern also conforming (in part) to the fastener pattern defined by the tunnel seat 154.

The first sidewall fastener plate 147 extends from the upper fastener plate 143 along the first sidewall portion 133 of the tunnel body 166 and is spaced apart from the lower fastener plate 145 by the first tunnel body registration tab 151. The first sidewall fastener plate 147 further defines a first sidewall fastener pattern that conforms (in part) to the fastener pattern defined by the tunnel seat 154. The second sidewall fastener plate 149 is similar to the first sidewall fastener plate 147, additionally extends from the upper fastener plate 143 along the second sidewall portion 135 of the tunnel body 166, and is further spaced apart from the lower fastener plate 145 by the second tunnel body registration tab 153. It is contemplated that the second sidewall fastener plate 149 define a second sidewall fastener pattern further conforming (in part) to the fastener pattern defined on the tunnel seat 154 for fixation of the tunnel body 166 to the rear panel 150 at the tunnel seat 154.

The first tunnel body registration tab 151 and the second tunnel body registration tab 153 are configured to register the tunnel body 166 to tunnel seat 154 to facilitate fixation of the tunnel body 166 to the rear panel 150 at the tunnel seat 154. In this respect the first tunnel body registration tab 151 extends between the first sidewall fastener plate 147 and the lower fastener plate 145, the second tunnel body registration tab 153 extends between the second sidewall fastener plate 149 and the lower fastener plate 145, and the second tunnel body registration tab 153 is laterally spaced from the first tunnel body registration tab 151 by a distance slightly greater than a lateral width of the tunnel seat 154. It is contemplated that the first tunnel body registration tab 151 and/or the second tunnel body registration tab 153 be relatively pliable, the first tunnel body registration tab 151 and/or the second tunnel body registration tab 153 flexing upon insertion into the tunnel seat 154 such that the tunnel body 166 is fixed therein at a location wherein fastener patterns defined with the flange portion 137 are registered to the fastener pattern defined in the tunnel seat 154, allowing the tunnel body 166 to be seated using the aforementioned position and pivot single installer method. It is also contemplated that either (or both) the first tunnel body registration tab 151 and the second tunnel body registration tab 153 may be notched to register the tunnel body 166 at the tunnel seat 154 defined by the rear panel 150. As will be appreciated by those of skill in the art in view of the present disclosure, registering and fixing the tunnel body 166 at the tunnel seat 154 using the first tunnel body registration tab 151 and the second tunnel body registration tab 153 allows for installation of the tunnel body 166 in a cantilevered arrangement by a single installer, simplifying fixation of the tunnel body 166 at the tunnel seat 154.

When fixed at the tunnel seat 154 the perforated plate extension 141 of the tunnel body 166 abuts the perforated plate 198. More specifically, the perforated plate extension 141 abuts the perforated plate 198 within the outboard passthrough 174 such that the ceiling portion 129 of the tunnel body 166 and the perforated plate extension 141 define a supply plenum extension 163 within the tunnel body 166. It is contemplated the ceiling portion 129 of the tunnel body 166 slope downwards form the upper fastener plate 143 and toward the facia portion 139 of the tunnel body 166 between the tunnel seat 154 and the outboard passthrough 174 relative to the transfer axis 120, the ceiling portion 129 and the perforated plate extension 141 cooperating to distribute and direct the purge fluid 10 entering the supply plenum extension 163 toward the floor portion 131 of the tunnel body 166 with a laminar flow pattern. It is also contemplated that the floor portion 131 slope downwards between the facia portion 139 of the tunnel body and the tunnel seat 154 to return the purge fluid 10 to the enclosure 158. In certain examples, the floor portion 131 of the tunnel body 166 intersecting the tunnel seat 154 at a location below the transfer paths between the front-end gate valve 138 and the load port 146. As will be appreciated by those of skill in the art in view of the present disclosure, intersection of the floor portion 131 with the tunnel seat 154 below substrates carried by the front-end substrate transfer robot 148 can limit contamination of substrates carried by the front-end substrate transfer robot 148 by the portion of the purge fluid 10 shunted through the tunnel body 166 by the ceiling portion 129 of the tunnel body 166, the floor portion 131 of the tunnel body 166, and the perforated plate extension 141.

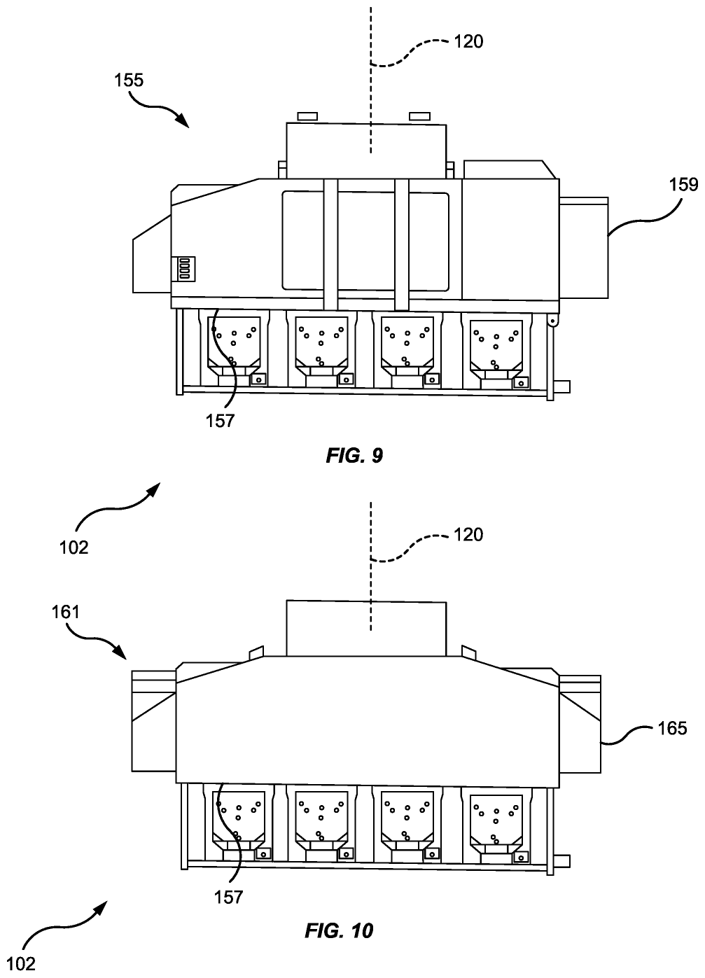

With reference to FIG. 9, it is contemplated that the frame assembly 140 (shown in FIG. 2) may have an asymmetric arrangement 155 in certain examples of the present disclosure. In this respect the EFEM 102, as shown in FIG. 9, may be asymmetrical relative to the transfer axis 120 when viewed from an inboard face 157 of the EFEM 102. The EFEM 102 may further have an asymmetric footprint 159 in such examples. Advantageously, the asymmetric arrangement 155 of the EFEM 102 in such examples allows the EFEM 102 to incorporate one or more accessories within the substrate transfer volume 164 (shown in FIG. 2) without requiring customization of the perforations within defied within the perforated plate 198 (shown in FIG. 3) to ensure uniformity of flow conditions within the frame assembly 140. Avoiding customization of the perforated plate 198 simplifies the EFEM 102 as a single perforated plate 198 may be employed in the EFEM 102 irrespective of whether the plate body 152 (shown in FIG. 6) or the tunnel body 166 (shown in FIG. 7) is fixed to the rear panel 150 (shown in FIG. 1) at the tunnel seat 154 (shown in FIG. 1).

With reference to FIG. 10, it is also contemplated that the frame assembly 140 (shown in FIG. 2) may have a symmetric arrangement 161 in certain examples of the present disclosure. In this respect the EFEM 102, as shown in FIG. 10, may be symmetrical relative to the transfer axis 120 when viewed from the inboard face 157 of the EFEM 102. In certain examples, the EFEM 102 may further have a symmetric footprint 165, the left-hand side of the EFEM 102 mirroring the right-hand side of the EFEM 102 when viewed along transfer axis 120 from the inboard face 157. Advantageously, the symmetric arrangement 161 of the frame assembly 140 in such examples can further simplify the EFEM 102, for example, by allowing identical parts to be used on mirroring locations on the EFEM 102. The symmetric arrangement 161 also causes substrates to experience a substantial identical environment during transfer between the EFEM 102 and the load lock module 104 (shown in FIG. 1) in semiconductor processing systems having dual transfer arrangements, such as in semiconductor processing systems employing dual chamber process modules and quad chamber process modules where substrates are transferred in pairs between the EFEM 102 and the load lock module 104.

With reference to FIG. 11, a semiconductor processing system 200 is shown. The semiconductor processing system 200 is similar to the semiconductor processing system 100 (shown in FIG. 1) and additionally includes a process module 202 with a dual chamber arrangement 204, a process chamber gate valve pair 206 including a first process module gate valve 208 and a second process module gate valve 210, and a back-end transfer module 212 with a back-end substrate transfer robot 214. The dual chamber arrangement 204 includes a first process chamber 216 and a second process chamber 218. In certain examples the first process chamber 216 and the second process chamber 218 may be configured to deposit material layers onto substrates, e.g., the substrate 2, using a plasma-enhanced method such as plasma-enhanced chemical vapor deposition or plasma-enhanced atomic layer deposition technique. In accordance with certain examples, the first process chamber 216 and the second process chamber 218 may be configured deposit material layers onto substrates using an atomic layer deposition technique.

The process chamber gate valve pair 206 couples the process module 202 to the back-end transfer module 212 and provides selective communication between the first process chamber 216 and the second process chamber 218, and the back-end substrate transfer robot 214. The back-end substrate transfer robot 214 is supported within a transfer chamber 220, includes an end effector pair 222, and is configured to transfer substrate pairs between the load lock module 104 and the process module 202 through the first process module gate valve 208 and the second process module gate valve 210. It is contemplated that the plate body 152 be fixed at the tunnel seat 154 and supported by the rear panel 150, and therethrough the frame assembly 140 (shown in FIG. 2), to axially space the process module 202 by a second spacing distance 224 from the frame assembly 140 along the transfer axis 120. It is contemplated that the second spacing distance 224 be selected such that a service space be defined between the process module 202 and the EFEM 102. The service space may conform to a requirement prescribed by a private and public regulatory body. As will be appreciated by those of skill in the art in view of the present disclosure, the second spacing distance 224 be provided using a singular EFEM arrangement limiting cost and complexity of the EFEM 102 relative to an EFEM having a customized configuration peculiar to the process module 202.

With reference to FIG. 12, a semiconductor processing system 300 is shown. The semiconductor processing system 300 is similar to the semiconductor processing system 100 (shown in FIG. 1) and additionally includes a process module 302 with a quad chamber arrangement 304, a process chamber gate valve pair 306 including a first process module gate valve 308 and a second process module gate valve 310, and a back-end transfer module 312 with a back-end substrate transfer robot 314. The quad chamber arrangement 304 includes a first process chamber 316, a second process chamber 318, a third process chamber 320, and a fourth process chamber 322. In certain examples the process chambers 316-322 may be configured to deposit material layers onto substrates, e.g., the substrate 2, using a plasma-enhanced method such as plasma-enhanced chemical vapor deposition or plasma-enhanced atomic layer deposition technique. In accordance with certain examples, the process chambers 316-322 may be configured deposit material layers onto substrates using an atomic layer deposition technique.

The process chamber gate valve pair 306 couples the process module 302 to the back-end transfer module 312 and provides selective communication between the process chambers 316-322, and the back-end substrate transfer robot 314. The back-end substrate transfer robot 314 is supported within a transfer chamber 324, includes an end effector pair 326, and is configured to transfer substrate pairs between the load lock module 104 and the process module 302 through the first process module gate valve 308 and the second process module gate valve 310. It is contemplated that the tunnel body 166 be fixed at the tunnel seat 154 and supported by the rear panel 150, and therethrough the frame assembly 140 (shown in FIG. 2), to axially space the process module 302 by a quad chamber spacing distance 328 from the frame assembly 140 along the transfer axis 120. It is contemplated that the quad chamber spacing distance 328 be selected such that a service space be defined between the process module 302 and the EFEM, for example, a service space also conforming to a requirement prescribed by a private and public regulatory body. As will be appreciated by those of skill in the art in view of the present disclosure, the quad chamber spacing distance 328 be provided using a singular EFEM arrangement, limiting cost and complexity of the EFEM 102 relative to an EFEM having a customized configuration peculiar to the process module 302.

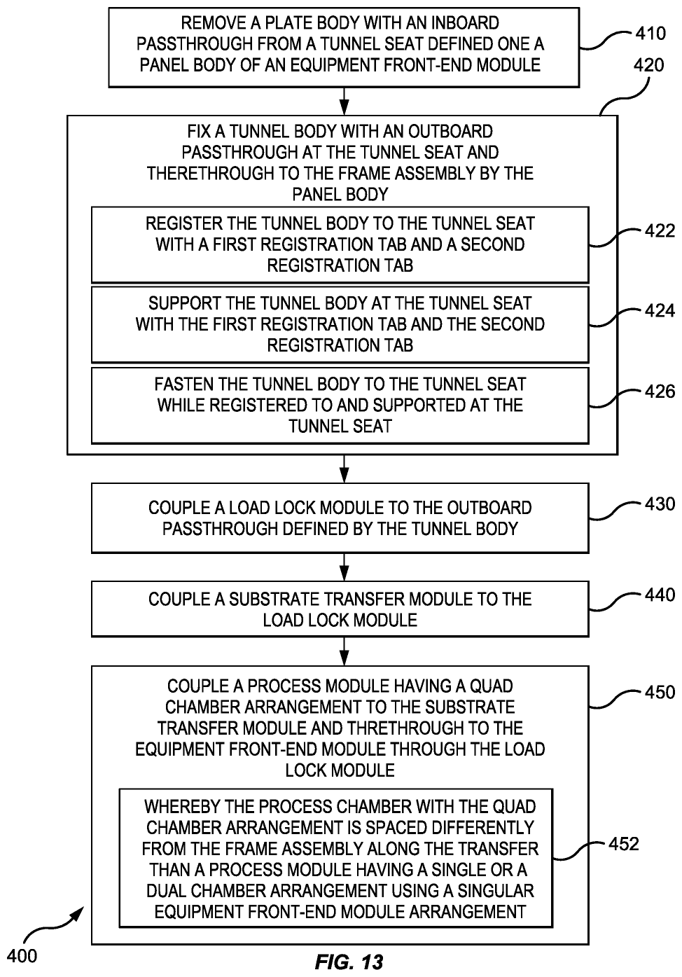

With reference to FIG. 13, a method 400 of making a semiconductor processing system, e.g., the semiconductor processing system 300 (shown in FIG. 12), is shown. The method 400 includes removing a plate body from an EFEM, e.g., the plate body 152 (shown in FIG. 1) from the EFEM 102 (shown in FIG. 1), as shown with box 410. The method 400 also includes fixing a tunnel body having an outboard passthrough to the EFEM, e.g., the tunnel body 166 (shown in FIG. 7) having the outboard passthrough 174 (shown in FIG. 7), as show with box 420. The method 400 further includes coupling a load lock module, e.g., the load lock module 104 (shown in FIG. 1), to the tunnel body at the outboard passthrough and a substrate transfer module, e.g., the back-end transfer module 106 (shown in FIG. 1), to the load lock module, as shown with box 430 and box 440. It is contemplated that the method 400 additionally include coupling a process module, e.g., the process module 302 (shown in FIG. 12) with the quad chamber arrangement 304 (shown in FIG. 12), to the back-end transfer module and therethrough to the EFEM through the back-end transfer module as shown with box 450.

Removing 410 the plate body from the tunnel seat may include removing fasteners fixing the plate body from the tunnel. Removing 410 the plate body from the tunnel seat may include removing the tunnel seat from a new-build EFEM, for example, when the plate body is employed as a shipping fixture in new-build EFEM for a semiconductor processing system having one or more process module with a quad chamber arrangement. Removing 410 the plate body from the tunnel seat may include removing the plate body from redeployed semiconductor processing system, such as when the EFEM is redeployed from a semiconductor processing system having a single chamber arrangement or a dual chamber arrangement to a semiconductor processing system having a quad chamber arrangement.

Fixing 420 the tunnel body to the tunnel seat may include registering the tunnel body at the tunnel seat using a first tunnel body registration tab and a second tunnel body registration tab, e.g., the first tunnel body registration tab 151 (shown in FIG. 8) and the second tunnel body registration tab 153 (shown in FIG. 8), as shown with box 422. Fixing the tunnel body to the tunnel seat may include supporting the tunnel body at the tunnel seat using the first tunnel body registration tab and the second tunnel body registration tab, for example, using a single installer assembly technique, as shown with box 424. Fixing the tunnel body to the tunnel seat may include fastening the tunnel body to the tunnel seat, for example using a rear panel fastener pattern defined the rear panel corresponding to fastener apertures defined on both the flange portion of the tunnel body and a plate body, as shown with box 426.

Coupling 430 the load lock module to the tunnel body may include registering one or more gate valve, e.g., the first front-end gate valve 226 (shown in FIG. 12) and the second front-end gate valve 228 (shown in FIG. 12), as also shown with box 430. The first front-end gate valve and the second front-end gate valve may at least partially abut a facia portion of the tunnel body, e.g., the facia portion 139 (shown in FIG. 8), as further shown with box 430. Coupling 440 the back-end transfer module to the load lock module may include spacing the back-end transfer module from tunnel body according to a quad chamber spacing distance, e.g., the quad chamber spacing distance 328 (shown in FIG. 12), as also shown with box 440. Coupling 440 the back-end transfer module to the load lock module may registering the back-end transfer module to the outboard passthrough defined by the tunnel body, as further shown with box 440.

Coupling 450 the process module to the back-end transfer module may include coupling more than one process module to the back-end transfer module. For example, the process module may be one of two, three, four or even more than four process modules coupled to the back-end transfer module and therethrough to the frame assembly through the outboard passthrough. Coupling 450 the process module to the back-end transfer chamber may include spacing the process module by a different distance than that of spacing associated with a process chamber having a single chamber arrangement or a dual chamber arrangement, as shown with box 452. For example, the back-end transfer chamber may be spaced further from the frame assembly by a distance corresponding to an axial depth of the perforated plate extension fixed within the tunnel body, as also shown with box 452.

The illustrations presented herein are not meant to be actual views of any particular material, structure, or device, but are merely idealized representations that are used to describe embodiments of the disclosure. The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

1. An equipment front-end module, comprising:
a frame assembly with a load port seat and a transfer robot seat;
a fan filter unit supported by the frame assembly;
a controls box enclosing the fan filter unit and supported by the fan filter unit;
a rear panel with a tunnel seat fixed to the frame assembly and is separated from the load port seat by the transfer robot seat; and
one of (a) a plate body with an inboard passthrough and (b) a tunnel body with an outboard passthrough fixed at the tunnel seat and coupled to the frame assembly by the rear panel to space a process chamber with a quad chamber arrangement from the frame assembly differently along a transfer extending through the tunnel seat than a process module having a single or a dual chamber arrangement using a singular equipment front-end module arrangement.

2. The equipment front-end module of claim 1, wherein the frame assembly comprises:
an inboard floor joist arranged along the transfer axis;
an outboard floor joist axially spaced apart from the inboard floor joist along the transfer axis, wherein the inboard floor joist and the outboard floor joist define the transfer robot seat; and
a front-end substrate transfer robot fixed to the transfer robot seat.

3. The equipment front-end module of claim 1, wherein the frame assembly comprises:
a first inboard post laterally offset from the transfer axis;
a second inboard post separated from the first inboard post by the transfer axis, wherein the first inboard post and the second inboard post define the load port seat; and
a load port fixed to the load port seat.

4. The equipment front-end module of claim 1, wherein the frame assembly comprises:
a first outboard post laterally offset from the transfer axis; and
a second outboard post separated from the first outboard post by the transfer axis, the first outboard post and the second outboard post supporting the rear panel.

5. The equipment front-end module of claim 4, wherein the plate body is fixed at the tunnel seat and coupled to the frame assembly by the rear panel, wherein the transfer axis extends through the inboard passthrough defined by the plate body.

6. The equipment front-end module of claim 5, further comprising a load lock module with a first front-end gate valve and a second front-end gate valve arranged along the transfer axis and abutting the plate body, wherein the first front-end gate valve and the second front-end gate valve are registered to the inboard passthrough.

7. The equipment front-end module of claim 4, wherein the tunnel body is fixed at the tunnel seat and coupled to the frame assembly by the rear panel, wherein the transfer axis extends through the outboard passthrough defined by the tunnel body.

8. The equipment front-end module of claim 7, further comprising a load lock module with a first front-end gate valve and a second front-end gate valve arranged along the transfer axis and abutting the plate body, wherein the first front-end gate valve and the second front-end gate valve are registered to the outboard passthrough.

9. The equipment front-end module of claim 1, wherein the plate body comprises:
a plate body fastener pattern extending about the inboard passthrough;
a plate body flange portion orthogonal relative to the plate body;
a first plate body registration tab laterally offset from the transfer axis and between the plate body flange portion and the plate body fastener pattern; and
a second plate body registration tab separated from the first plate body registration tab by the transfer axis, the second plate body registration tab between the plate body flange portion and the plate body fastener pattern.

10. The equipment front-end module of claim 1, wherein the tunnel body comprises:
a flange portion axially offset from a facia portion defining the outboard passthrough;
a ceiling portion extending axially along the transfer axis and coupling the flange portion to the facia portion of the tunnel body; and
a floor portion extending axially along the transfer axis and coupling the flange portion to the facia portion, the floor portion separated from the ceiling portion by the transfer axis.

11. The equipment front-end module of claim 10, wherein the ceiling portion is oblique relative to the transfer axis, wherein the floor portion is oblique relative to the transfer axis, and wherein the floor portion of the tunnel body slopes toward the flange portion at a greater angle than the ceiling portion of the tunnel body.

12. The equipment front-end module of claim 10, wherein the flange portion comprises:
an upper fastener plate parallel to the facia portion and extending upwards from the ceiling portion of the tunnel body;
a lower fastener plate orthogonal to the upper fastener plate and extending axially from the floor portion of the tunnel body;
a first tunnel body registration tab laterally offset from the transfer axis and separating the upper fastener plate from the lower fastener plate; and
a second tunnel body registration tab separated from the first tunnel body registration tab by the transfer axis, the second tunnel body registration tab separating the upper fastener plate from the lower fastener plate.

13. The equipment front-end module of claim 10, wherein the floor portion of the tunnel body intersects the rear panel below a transfer space defined within the equipment front-end module to return purge circulated through the tunnel body below substrates being transferred to and from the outboard passthrough defined by the tunnel body.

14. The equipment front-end module of claim 1, further comprising a perforated plate supported within the equipment front-end module between the fan filter unit and the transfer robot seat to distribute a purge fluid within a transfer space within the frame assembly.

15. The equipment front-end module of claim 13, wherein the tunnel body has a perforated plate extension fixed within the tunnel body and parallel to the transfer axis, wherein the perforated plate extension abuts the perforated plate supported within the equipment front-end module.

16. The equipment front-end module of claim 13, wherein the plate body abuts the perforated plate supported within the equipment front-end module in the tunnel seat.

17. A semiconductor processing system, comprising:
an equipment front-end module as recited in claim 1, further comprising a perforated plate supported within the equipment front-end module between the fan filter unit and the transfer robot seat to distribute a purge fluid within the EFEM;
a load lock module axially spaced apart from the equipment front-end module along the transfer axis; and
one of (a) a process module having a dual chamber arrangement and (b) a process module having a quad chamber arrangement coupled the load lock and therethrough to the equipment front-end module.

18. The semiconductor processing system of claim 17, wherein the plate body is fixed at the tunnel seat and supported therethrough by the rear panel, wherein the plate body abuts the perforated plate in the tunnel seat, and wherein the process module is coupled to the load lock module and therethrough to the equipment front-end module.

19. The semiconductor processing system of claim 17, wherein the tunnel body is fixed at the tunnel seat and supported therethrough by the rear panel, wherein the tunnel body includes a perforated plate extension fixed therein and abutting the perforated plate within the tunnel seat, and wherein the process module having the quad chamber arrangement is coupled to the load lock module and therethrough to the equipment front-end module.

20. A method of making a semiconductor processing system, the method comprising:
at an equipment front-end module including a frame assembly with a load port seat and a transfer robot seat, a fan filter unit supported by the frame assembly, a controls box enclosing the fan filter unit and supported by the fan filter unit, and a rear panel with a tunnel seat fixed to the frame assembly and separated from the load port seat by the transfer robot seat,
removing a plate body with an inboard passthrough from the tunnel seat;
fixing a tunnel body with an outboard passthrough at the tunnel seat and therethrough to the frame assembly by the rear panel;
coupling a load lock module to the outboard passthrough defined by the tunnel body;
coupling a substrate transfer module to the load lock module; and
coupling a process module having a quad chamber arrangement to the substrate transfer module and therethrough to the equipment front-end module through the load lock module,
whereby the process module with the quad chamber arrangement is spaced differently from the frame assembly along the transfer than a process module having a single or a dual chamber arrangement using a singular equipment front-end module arrangement.
